(19) United States
(12) Patent Application Publication
(10) Pub. No.: US 2022/0352870 A1
(43) Pub. Date: Nov. 3, 2022

(54) COMPOSITE SUBSTRATE, SURFACE ACOUSTIC WAVE RESONATOR, AND FABRICATING METHODS THEREOF

(71) Applicant: Ningbo Semiconductor International Corporation, Ningbo (CN)

(72) Inventors: Herb He HUANG, Ningbo (CN); Hailong LUO, Ningbo (CN); Wei LI, Ningbo (CN); Fei QI, Ningbo (CN)

(21) Appl. No.: 17/867,629

(22) Filed: Jul. 18, 2022

Related U.S. Application Data
(63) Continuation of application No. PCT/CN2020/135659, filed on Dec. 11, 2020.

(30) Foreign Application Priority Data
Jan. 17, 2020 (CN) 202010054453.8

(51) Int. Cl. H03H 9/02; H03H 3/08; H03H 9/25

(52) U.S. Cl. CPC H03H 9/02574; H03H 3/08; H03H 9/02559; H03H 9/02637; H03H 9/25

(57) ABSTRACT

A composite substrate, a surface acoustic wave resonator and their fabricating method are provided. The fabricating method of the composite substrate includes: providing a first substrate; forming a liner layer including at least a polycrystalline material layer on the first substrate; depositing a piezoelectric sensing film for generating acoustic resonance on the polycrystalline material layer by a physical or chemical deposition method; and performing recrystallization annealing treatment on the piezoelectric sensing film, to make the piezoelectric sensing film reach a polycrystalline state. The recrystallization annealing treatment includes a heating process and a cooling process, and the heating process includes heating the piezoelectric sensing film to make the piezoelectric sensing film reach a molten state.

### CROSS-REFERENCES TO RELATED APPLICATION

This application is a continuation application of PCT Patent Application No. PCT/CN2020/135659, filed on Dec. 11, 2020, which claims priority to Chinese patent applications No. 202010054453.8, filed on Jan. 17, 2020, the entirety of all of which is incorporated herein by reference.

### FIELD OF THE DISCLOSURE

The present disclosure generally relates to the field of manufacture of semiconductor devices and more particularly, relates to a composite substrate, a surface acoustic wave resonator, and their fabricating methods.

### BACKGROUND

With the development of mobile communication technology, the amount of mobile data transmission is also rising rapidly. Therefore, under the premise of limited frequency resources and the use of mobile communication devices as few as possible, improving the transmission power of wireless power transmitting devices such as wireless base stations, micro base stations or repeaters has become a problem that must be considered. The requirements for filter power in front-end circuits of mobile communication equipment are also increasing.

At present, the high-power filters in wireless base stations and other equipment are mainly cavity filters, and their power can reach hundreds of watts. But the size of such filters is too large. Dielectric filters are also used in some devices, the average power of which can reach more than 5 watts, and the size of such filters is also large. Due to its large size, this cavity filter cannot be integrated into radio frequency front-end chips.

One of the main filters in thin-film filters based on semiconductor microfabrication technology is a surface acoustic wave Resonator (SAW). A piezoelectric substrate used in a surface acoustic wave resonator is usually formed by bonding and thinning a silicon substrate and a single crystal piezoelectric wafer. However, the single crystal piezoelectric wafer material is very brittle and prone to cracking in the semiconductor process, requiring a special design of the process menu and reducing production efficiency. Moreover, the current largest wafer size is still 6 inches. Even though many filter manufacturers use a 4-inch process for their process lines, the number of filter chips produced on a single wafer is small. In addition, the cost of a single wafer is relatively high, such that the cost of the surface acoustic wave filter cannot be further reduced.

Therefore, how to solve the fragmentation of the piezoelectric wafer in the process, improve the production efficiency of the substrate, and reduce the cost, are the current problem.

### SUMMARY

The present disclosure provides a composite substrate, a surface acoustic wave resonator, and their fabricating methods, to at least partially alleviate the problem of the fragmentation of the piezoelectric wafer in the process, the poor production efficiency, and the high cost.

One aspect of the present disclosure provides a fabricating method of a composite substrate. The method includes: providing a first substrate; forming a liner layer including at least a polycrystalline material layer on the first substrate; depositing a piezoelectric sensing film for generating acoustic resonance on the polycrystalline material layer by a physical or chemical deposition method; and performing recrystallization annealing treatment on the piezoelectric sensing film, to make the piezoelectric sensing film reach a polycrystalline state. The recrystallization annealing includes a heating process and a cooling process, and the heating process includes heating the piezoelectric sensing film to make the piezoelectric sensing film reach a molten state.

Another aspect of the present disclosure provides a composite substrate. The composite substrate includes: a first substrate; a liner layer on the first substrate including at least a polycrystalline material layer; and a piezoelectric sensing film for generating acoustic resonance on the polycrystalline material layer. The piezoelectric sensing film is in a polycrystalline state.

Another aspect of the present disclosure provides a surface acoustic wave resonator. The resonator includes a composite substrate. The composite substrate includes: a first substrate; a liner layer on the first substrate including at least a polycrystalline material layer; and a piezoelectric sensing film for generating acoustic resonance on the polycrystalline material layer. The piezoelectric sensing film is in a polycrystalline state.

Another aspect of the present disclosure provides a fabricating method of a surface acoustic wave resonator. The method includes: providing a composite substrate including a first substrate, a liner layer on the first substrate including at least a polycrystalline material layer, and a piezoelectric sensing film for generating acoustic resonance on the polycrystalline material layer; and forming a first interdigital transducer and a second interdigital transducer on the piezoelectric sensing film. The piezoelectric sensing film is in a polycrystalline state.

Other aspects or embodiments of the present disclosure can be understood by those skilled in the art in light of the description, the claims, and the drawings of the present disclosure.

### BRIEF DESCRIPTION OF THE DRAWINGS

Exemplary embodiments of the present disclosure will be described in detail in conjunction with the accompanying drawings, to illustrate features, advantages, and other objects of the present disclosure more apparently. In the exemplary embodiments of the present disclosure, the same reference numerals generally refer to the same parts.

FIG. 1 illustrates an exemplary fabricating method of a composite substrate consistent with various disclosed embodiments of the present disclosure;

FIG. 2 to FIG. 4 illustrate exemplary structures of a composite substrate consistent with various disclosed embodiments of the present disclosure;

FIG. 5 illustrates an exemplary structure of a surface acoustic wave resonator consistent with various disclosed embodiments of the present disclosure; and

FIG. 6 illustrates another exemplary structure of a surface acoustic wave resonator consistent with various disclosed embodiments of the present disclosure.

### NUMBER LITERALS

10—first substrate; 20—liner layer; 30—piezoelectric sensing film; 41—first interdigital transducer; 42—second interdigital transducer; 50—second substrate; 51—first chamber.

### DETAILED DESCRIPTION

The present disclosure will be further described in detail below with reference to the accompanying drawings and specific embodiments. The advantages and features of the present disclosure will become clearer from the following description and accompanying drawings. However, it should be noted that the concept of the technical solution of the present disclosure may be implemented in various forms, and is not limited to the embodiments described herein. The accompanying drawings are all in a very simplified form and use inaccurate scales, and are only used to facilitate and clearly assist the illustration of the embodiments of the present disclosure.

It should be understood that when a device or a layer is referred to as being “on”, “adjacent to”, “connected to”, or “coupled to” other devices or layers, it can be directly on, adjacent to, connected to or coupled to the other devices or layers, or intermediate devices or layers may be present. In contrast, when a device is referred to as being “directly on”, “directly adjacent to”, “directly connected to”, or “directly coupled to” other devices or layers, there are no intermediate devices or layers present. It should be understood that, although the terms “first”, “second”, “third”, etc. may be used to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the scope of the present disclosure.

Spatial relational terms such as “under”, “below”, “below”, “under”, “above”, “on”, etc., may be used herein for convenience of description of the relationship of one element or feature with respect to other elements or features shown in the drawings. It should be understood that the spatially relative terms are intended to encompass different orientations of the device in use and operation in addition to the orientation shown in the drawings. For example, if the device in the drawings is turned over, elements or features described as “below”, “under”, or “beneath” other elements or features may then be oriented “above” the other elements or features. Thus, the exemplary terms “below” and “under” can encompass both an orientation of above and below. Or, the device may be otherwise oriented (rotated 90 degrees or at other orientations) and may be interpreted using the spatial descriptors herein accordingly.

The terminology used herein is for the purpose of describing particular embodiments only and is not intended to limit the scope of the present disclosure. As used herein, the singular forms “a”, “an”, and “the” are intended to include the plural forms as well, unless the context clearly dictates otherwise. It is also to be understood that the terms “compose” and/or “include”, when used in this specification, are used to describe the presence of stated features, integers, steps, operations, elements and/or components, but do not exclude presence or addition of other one or more features, integers, steps, operations, elements, parts and/or groups. As used herein, the term “and/or” includes any and all combinations of the associated listed items.

If a method herein includes a series of steps, the order of the steps presented herein is not necessarily the only order in which the steps may be performed, and some of the steps may be omitted and/or some other steps not described herein may be added to this method. If the components in a certain drawing are the same as the components in other drawings, although these components can be easily identified in all the drawings, in order to make the description of the drawings clearer, numbers of all the same components may not be included in each drawing.

### Exemplary Embodiment One

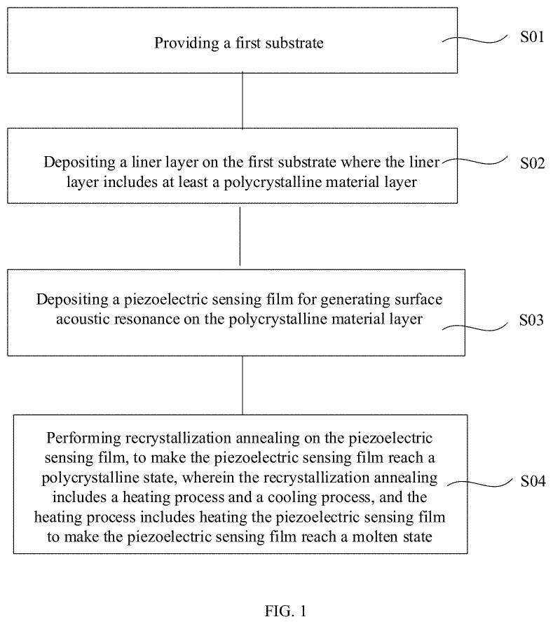

The present disclosure provides a fabricating method for a composite substrate. FIG. 1 illustrates an exemplary fabricating method of a composite substrate according to one embodiment of the present disclosure. As shown in FIG. 1, the fabricating method of a composite substrate may include:

S01: providing a first substrate;

S02: depositing a liner layer on the first substrate, where the linear layer may at least include a polycrystalline material layer;

S03: depositing a piezoelectric sensing film for generating acoustic resonance on the polycrystalline material layer by using a physical or chemical deposition method; and

S04: performing a recrystallization annealing process on the piezoelectric sensing film such that the piezoelectric sensing film becomes a polycrystalline state, where the recrystallization annealing process may include a heating process and a cooling process, and the heating process may include heating the piezoelectric sensing film such that the piezoelectric sensing film becomes melt.

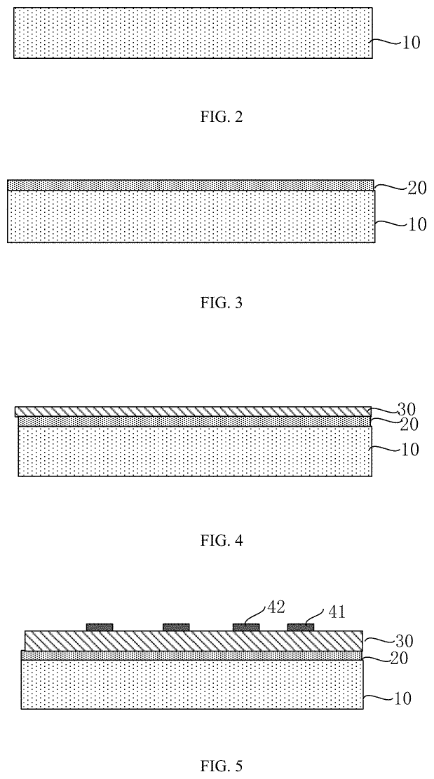

FIG. 2 to FIG. 4 illustrate exemplary structures corresponding to different stages of a fabricating method of a composite substrate consistent with various disclosed embodiments of the present disclosure. As shown in FIG. 2 to FIG. 4, the fabricating method of a composite substrate may include following stages.

As shown in FIG. 2, S01 may be executed to provide a first substrate 10.

The material of the first substrate 10 may be selected from a material suitable for semiconductor technology, which can be at least one of: silicon (Si), germanium (Ge), silicon germanium (SiGe), silicon carbide (SiC), carbon silicon germanium (SiGeC), indium arsenide (InAs), gallium arsenide (GaAs), indium phosphide (InP) or other III/V compound semiconductors, or silicon-on-dielectric (SOI), stacked-silicon-on-dielectric (SSOI), stacked silicon germanium on dielectric (S-SiGeOI), silicon germanium on dielectric (SiGeOI), germanium on dielectric (GeOI), or a double-side polished wafer (DSP). The first substrate 10 may also be a ceramic substrate such as an alumina substrate, a quartz substrate, or a glass substrate.

In one embodiment, the first substrate 10 may be made of a material including P-type silicon with a resistance value larger than 10K Ohm cm. The reason for choosing a high-resistance substrate material is that when there is an alternating current above the first substrate, the alternating current generates electromagnetic waves, and the electromagnetic wave radiation loses part of the electric energy. Under the low-frequency condition, the radiation loss is small, but under the high-frequency condition, the radiation loss increases. The use of high-resistance substrate materials may reduce electromagnetic wave radiation and reduce power loss.

As shown in FIG. 3, S02 may be performed to deposit the liner layer 20 on the first substrate 10. The liner layer 20 may at least include the polycrystalline material layer.

The polycrystalline material layer may have a good crystal orientation. In the later process, when the formed piezoelectric sensing film is crystallized, the piezoelectric sensing film may be crystallized according to the crystal orientation of the polycrystalline material layer. The material of the polycrystalline material layer may include polycrystalline aluminum oxide, polycrystalline silicon dioxide, or polycrystalline silicon carbide. In this embodiment, the liner layer 20 may be made of polycrystalline aluminum oxide. The polycrystalline material layer may have a good crystal orientation, such that the piezoelectric sensing film with a better crystal orientation and a polycrystalline state may be obtained after the annealing process on the piezoelectric sensing film deposited thereon. Compared with the traditional method of bonding a piezoelectric wafer on a substrate, the process of forming the polycrystalline piezoelectric sensing film on the substrate may avoid the problems of fragmentation of the piezoelectric crystal, low production efficiency, and high cost.

The deposition of the liner layer 20 (the deposition of the polycrystalline material layer in the present embodiment) on the first substrate may include: depositing the polycrystalline material layer with a thickness of about 2000 Å to about 1000 Å on the first substrate 10 by a physical vapor deposition method or a chemical vapor deposition method. The thickness of the polycrystalline material layer cannot be too thin, otherwise the quality of the polycrystalline material layer itself may be not good and the quality of the piezoelectric sensing film formed on it in the later process may be affected. Also, a certain thickness may be required such that the polycrystalline material layer is able to be used as an acoustic wave reflection layer. The polycrystalline material layer does not need to be too thick, otherwise the production efficiency may be affected.

In another embodiment, the liner layer 20 may further include an acoustic wave reflection layer, and the acoustic wave reflection layer may be formed between the polycrystalline material layer and the first substrate 10. The acoustic wave reflection layer may have a large impedance mismatch with the piezoelectric sensing film formed in the later process. When the acoustic wave is transmitted to the acoustic wave reflection layer, the acoustic wave reflection layer may reflect the acoustic wave back into the piezoelectric sensing film, such that the energy loss of the acoustic wave may be reduced. The acoustic wave reflection layer may be made of a material including aluminum oxide, silicon dioxide, silicon nitride, or silicon carbide.

In one embodiment, the deposition of the liner layer 20 (including the acoustic wave reflection layer and the polycrystalline material layer) on the first substrate 10 may include: depositing the acoustic wave refection layer with a thickness of about 2000 Å to about 1000 Å on the first substrate 10 by a physical vapor deposition method or a chemical vapor deposition method; and depositing the polycrystalline material layer with a thickness of about 2000 Å to about 1000 Å on the acoustic wave reflection layer by a physical vapor deposition method or a chemical vapor deposition method. The polycrystalline material layer may be formed by an existing method and will not be described here.

In some embodiments, the acoustic wave reflection layer and the polycrystalline material layer may be the same layer, and the material of the liner layer may be polycrystalline aluminum oxide, polycrystalline silicon dioxide, or polycrystalline silicon carbide.

As shown in FIG. 4, S03 may be performed to deposit the piezoelectric sensing film 30 for generating the acoustic resonance on the polycrystalline material layer by a physical or chemical deposition method.

The piezoelectric sensing thin film material may be deposited on the polycrystalline material layer by a physical vapor deposition, and the thickness of the piezoelectric sensing thin film material may be usually in the range of about 0.01 to about 10 In one embodiment, the thickness may be in the range of 0.4 μm to 5 μm. The selection of the thickness of the piezoelectric sensing film material mainly considers two aspects including the performance of the resonator that is achieved and the stability of the process that can be controlled. The physical vapor deposition method may include vacuum evaporation, sputtering, or ion plating. The purity of the piezoelectric material target used in the physical vapor deposition may be larger than 99.99%, to ensure that the deposited piezoelectric sensing film has fewer impurities or defects and that the yield of resonators and filters is able to reach the target value that is suitable for massive production. The formed piezoelectric sensing film 30 may be in a microcrystalline or amorphous state. The piezoelectric inductive film 30 deposited in one embodiment may be used for the surface acoustic wave resonator. The piezoelectric sensing film 30 may be made of a material including lithium niobate, lithium tantalate, lithium tetraborate, bismuth germanate, lanthanum silicate, aluminum orthophosphate or potassium niobate, or a combination thereof.

When depositing the piezoelectric sensing film made of lithium niobate, a sputtering target formed by sintering raw materials of Ta₂O₅ and lithium acetate, and a gas used for the sputtering plasma source may be argon.

As shown in FIG. 4, S04 may be performed to perform the recrystallization annealing process on the piezoelectric sensing film 30, to make the piezoelectric sensing film 30 become a polycrystalline state. The crystallization annealing process may include a heating process and a cooling process. The heating process may include heating the piezoelectric sensing film 30 to make the piezoelectric sensing film 30 reach a molten state.

The piezoelectric sensing film 30 may be recrystallized and annealed at a temperature at which the piezoelectric sensing film 30 reaches a molten state. There may be two methods for recrystallization annealing treatment. One is to uniformly heat the first substrate, the liner layer, and the piezoelectric sensing film as a whole. For example, the piezoelectric sensing film 30, the first substrate 10, and the liner layer 20 may be heated as a whole in a furnace tube, to make the piezoelectric sensing film 30 reach a molten state, such that the piezoelectric sensing film 30 is recrystallized. Another method may be to locally heat the piezoelectric sensing film 30. For example, a laser may be used to scan and heat the piezoelectric sensing film 30, to make the piezoelectric sensing film 30 reach a molten state and recrystallize the piezoelectric sensing film 30.

The first recrystallization annealing method may specifically include: placing the first substrate 10 on which the piezoelectric sensing film 30 is deposited into a high temperature furnace, such as a horizontal furnace, a vertical furnace, or a rapid thermal processing (RTP) system; and heating at 1100˜1200 degrees for 2 to 5 minutes.

The second recrystallization annealing method may specifically include: in a vacuum, nitrogen, or oxygen atmosphere, using a pulsed laser of 0.8-15 joules per square centimeter and the laser frequency of 1-10 KHz, to act on the piezoelectric sensing film for 5 seconds to 20 seconds (different piezoelectric sensing films may have different action times), such that the piezoelectric sensing film is heated to 1000-1400 degrees in the form of scanning to reach a molten state and recrystallize.

In one embodiment, the piezoelectric sensing film 30 may be made of lithium niobate or lithium tantalate, and the recrystallization annealing treatment of the piezoelectric sensing film 30 by the furnace tube annealing may include: uniformly heating the first substrate 10, the liner layer 20 and the piezoelectric sensing film 30 as a whole to 1100 to 1300 degrees with the heating time of 5 to 30 seconds, and then cooling to room temperature. The cooling rate may be lower than 5 Celsius degrees per second to prevent the piezoelectric sensing film 30 from peeling or breaking.

In one embodiment, after recrystallization of the piezoelectric sensing film 30, the method may further include: polishing an upper surface of the piezoelectric sensing film 30 by a mechanical polishing method or a chemical mechanical polishing method. For example, the piezoelectric sensing film 30 may be polished by the chemical mechanical polishing (CMP) method. The surface roughness index of the piezoelectric sensing film 30 after polishing may be lower than 10 nanometers. After polishing the upper surface of the piezoelectric sensing film 30, the method may further include: trimming the upper surface of the piezoelectric sensing film 30 through an ion beam trimming process, such that the surface thickness uniformity of the piezoelectric sensing film 30 after trimming is less than 2%. The trimming precision of the ion beam is able to reach nanometer level, and the local and overall surface heights of the piezoelectric sensing film 30 may be trimmed. The heights of the trimmed piezoelectric sensing film on the whole substrate may be consistent, improving the performance consistency of adjacent devices and the yield of the resonator.

In one embodiment, the ion beam trimming process may use following parameters: an ion beam current of 25 mA to 200 mA, and a scanning time of 30 seconds to 10 minutes.

By polishing and performing ion beam trim on the surface of the recrystallized piezoelectric sensing film, the surface flatness of the piezoelectric sensing film and the piezoelectric characteristic of the piezoelectric sensing film may be improved.

### Exemplary Embodiment Two

The present disclosure also provides a composite substrate. FIG. 4 illustrates an exemplary composite substrate according to one embodiment of the present disclosure. As shown in FIG. 4, the composite substrate may include:

a first substrate 10;

a liner layer 20 on an upper surface of the first substrate 10, where the liner layer 20 may include at least a polycrystalline material layer; and

a piezoelectric sensing film 30 for generating acoustic resonance, where the piezoelectric sensing film 30 is disposed on the polycrystalline material layer and is in a polycrystalline state.

In one embodiment, the first substrate 10 may be made of a material including P-type silicon with a resistance value larger than 10K Ohm cm. The reason for choosing a high-resistance substrate material is that when there is an alternating current above the first substrate, the alternating current generates electromagnetic waves, and the electromagnetic wave radiation loses part of the electric energy. Under the low-frequency condition, the radiation loss is small, but under the high-frequency condition, the radiation loss increases. The use of high-resistance substrate materials may reduce electromagnetic wave radiation and reduce power loss.

In one embodiment, the liner layer 20 may have a single-layer structure, that is, the liner layer 20 may be a polycrystalline material layer. The polycrystalline material layer may be made of a material including polycrystalline aluminum oxide, polycrystalline silicon dioxide, or polycrystalline silicon carbide.

In another embodiment, the liner layer may further include an acoustic wave reflection layer disposed between the first substrate and the polycrystalline material layer. The acoustic wave reflection layer may be made of a material including aluminum oxide, silicon dioxide, silicon nitride or silicon carbide. It should be noted that, in one embodiment, the acoustic wave reflection layer and the polycrystalline material layer may be the same layer, and in this case, the material of the liner layer may include polycrystalline aluminum oxide, polycrystalline silicon dioxide, or polycrystalline silicon carbide. The function of the acoustic wave reflection layer may include: when the longitudinal acoustic wave is transmitted to the acoustic wave reflection layer, it is reflected back into the piezoelectric sensing film, to reduce the energy loss of the acoustic wave and improve the Q value of the resonator.

In another embodiment, the first substrate may further include an acoustic reflection structure including a cavity or a Bragg reflection layer. The acoustic reflection structure may be used to reflect the longitudinal acoustic wave transmitted into the first substrate by the piezoelectric sheet, to further reduce the energy loss of the acoustic wave.

### Exemplary Embodiment Three

The present disclosure also provides a fabricating method for forming a surface acoustic wave resonator. FIG. 5 illustrates an exemplary structure of a surface acoustic wave resonator consistent with various disclosed embodiments of the present disclosure. As shown in FIG. 5, the method may include:

providing a composite substrate; and

forming a first interdigital transducer 41 and a second interdigital transducer 42 on a piezoelectric sensing film 30.

A first conductive film may be formed over the surface of the piezoelectric sensing film 30. The first conductive film may be formed on the surface of the piezoelectric sensing film by physical vapor deposition such as magnetron sputtering, evaporation, or chemical vapor deposition. The material of the first conductive film may be any suitable conductive material, such as a metal including molybdenum (Mo), aluminum (Al), copper (Cu), tungsten (W), tantalum (Ta), platinum (Pt), ruthenium (Ru), rhodium (Rh), iridium (Ir), chromium (Cr), titanium (Ti), gold (Au), osmium (Os), rhenium (Re), palladium (Pd), platinum gold, nickel, or any alloy thereof.

The first conductive film may be patterned to form the first interdigital transducer 41 and the second interdigital transducer 42. In one embodiment, the formed resonator may be a surface acoustic wave resonator (SAW), and the method for patterning the first conductive film may include dry etching or wet etching. The first interdigital transducer 41 may include a plurality of first conductive interdigital fingers that are parallel and interval to each other, and the second interdigital transducer 42 may include a plurality of second conductive interdigital fingers that are parallel to and interval to each other. The first interdigital transducer 41 and the second interdigital transducer 42 may be parallel to each other. In one embodiment, the plurality of first conductive interdigital fingers and the plurality of second conductive interdigital fingers may be parallel and staggered to each other. In another embodiment, the first interdigital transducer 41 and the second interdigital transducer 42 may be arranged separately, and the plurality of first conductive interdigital fingers and the plurality of second conductive interdigital fingers may be parallel to each other, but not staggered with each other. Of course, in some other embodiments, the first interdigital transducer 41 and the second interdigital transducer 42 may not be parallel, as long as they do not intersect.

In one embodiment, the composite substrate may be formed with an acoustic reflection structure, and the first interdigital transducer and second interdigital transducer may be formed above an area enclosed by the acoustic reflection structure.

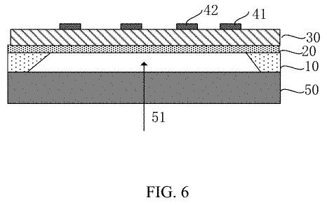

As shown in FIG. 6, in one embodiment, the acoustic reflection structure may include a first cavity 51. The first cavity 51 may be formed by:

on a side of the first substrate 10 away from the piezoelectric sensing film (a bottom surface of the first substrate), using an etching process to form the first cavity 51, where a bottom surface of the liner layer 20 is exposed by a bottom of the first cavity 51; and

providing a second substrate 50 to be bonded to the bottom surface of the first substrate 10 to seal the first cavity 51.

Before forming the first cavity 51, the bottom surface of the first substrate 10 may be thinned such that the thickness of the first substrate 10 is 0.5 to 5 μm. The thickness of the second substrate 50 may be about 300 μm to about 500 μm.

In another embodiment, the acoustic reflection structure may be a Bragg reflection layer. The Bragg reflection layer may be formed by:

forming a second cavity on a bottom surface of the first substrate through an etching process, where a bottom of the second cavity exposes the liner layer; and

forming at least two groups of staggered first acoustic impedance layers and second acoustic impedance layers on the bottom of the second cavity. A hardness of the first acoustic impedance layers may be higher than the hardness of the second acoustic impedance layers. The first acoustic impedance layers may be made of a metal including tungsten or a medium including silicon carbide or diamond. The second acoustic impedance layer may be made of a material including silicon oxide or silicon nitride.

### Exemplary Embodiment Four

The present disclosure also provides a surface acoustic wave resonator. The surface acoustic wave resonator may include a composite substrate provided by various embodiments of the present disclosure. The structure of the surface acoustic wave resonator may be made reference to the fabricating method provided by the above embodiments.

Compared with an amorphous piezoelectric sensing film, the polycrystalline piezoelectric sensing film may have higher crystallinity and a higher piezoelectric coupling coefficient, therefore improving the performance of the surface acoustic wave filter.

Further, the polycrystalline material layer itself or the acoustic wave reflection layer formed between the first substrate and the polycrystalline material layer may reflect the longitudinal acoustic wave back into the piezoelectric sensing film when the longitudinal acoustic wave is transmitted to the acoustic wave reflection layer. Therefore, the acoustic wave energy loss may be reduced and the Q value of the resonator may be improved.

In existing technologies, single crystals are generally used as the piezoelectric film of the surface acoustic wave resonator, and polycrystalline is not used as the piezoelectric film of the surface acoustic wave resonator since the industry generally believes that the polycrystalline piezoelectric film is not conducive to the propagation of acoustic waves and will affect the performance of the resonator. However, in the present disclosure, it is found that although the polycrystalline piezoelectric film is composed of single crystal particles which are not arranged neatly and have no consistent crystal orientation, the crystal orientation of the piezoelectric film has very little influence on the piezoelectric performance. Correspondingly, in the present disclosure, the device performance of the polycrystalline piezoelectric thin film may be consistent with that of the single-crystal thin film. In the present disclosure, the polycrystalline material layer may be formed on the substrate. The polycrystalline material layer may have a good crystal orientation, such that the piezoelectric sensing film deposited thereon may have a better crystal orientation and a higher crystal orientation after the annealing process. Compared with the traditional method of bonding piezoelectric wafer on the substrate, the process of forming the polycrystalline piezoelectric sensing film on the substrate may avoid the problems of fragmentation of the piezoelectric crystal, low production efficiency and high cost. The polycrystalline piezoelectric film may be formed after deposition and recrystallization. Compared with the existing single crystal piezoelectric film, the growth process may be simple and the cost may be low. Compared with single-crystal piezoelectric film, the polycrystalline piezoelectric film may have better structural strength and may be not easy to be broken. Further, deposition and annealing technology may have no restrictions on wafer size, and may be applied to 6-inch, 8-inch or other production processes. Moreover, since the stress direction of the polycrystalline particles is not concentrated, it may not cause a large stress in a single direction, which may greatly reduce the risk of cracking of the piezoelectric film compared with single crystals.

Further, the surface roughness index of the polycrystalline piezoelectric film may be less than 10 nm, and the flatness may be very high. Therefore, the polycrystalline piezoelectric film may minimize the scattering of acoustic wave energy.

Further, the polycrystalline material layer itself or the acoustic wave reflection layer formed between the substrate and the polycrystalline material layer may reflect the longitudinal acoustic wave back into the piezoelectric sensing film, when the longitudinal acoustic wave is transmitted to the acoustic wave reflection layer, which may reduce the acoustic wave energy loss and improve the Q value of the resonator.

Further, by polishing and ion beam trimming the surface of the crystallized piezoelectric sensing film, the surface flatness and the piezoelectric properties of the piezoelectric sensing film may be improved.

Each embodiment in the present disclosure is described in a related manner, and the same and similar parts between the various embodiments may be referred to each other, and each embodiment focuses on the differences from other embodiments. In particular, for the structural embodiments, since they are basically similar to the method embodiments, the description is relatively simple, and reference may be made to the partial descriptions of the method embodiments for related parts.

The embodiments disclosed herein are exemplary only. Other applications, advantages, alternations, modifications, or equivalents to the disclosed embodiments are obvious to those skilled in the art and are intended to be encompassed within the scope of the present disclosure.

What is claimed is:

1. A method of fabricating a composite substrate, comprising:
providing a first substrate;
forming a liner layer on the first substrate, wherein the liner layer includes at least a polycrystalline material layer;
depositing a piezoelectric sensing film for generating acoustic resonance on the polycrystalline material layer by a physical or chemical deposition method; and
performing recrystallization annealing treatment on the piezoelectric sensing film, to make the piezoelectric sensing film reach a polycrystalline state, wherein the recrystallization annealing treatment includes a heating process and a cooling process, and the heating process includes heating the piezoelectric sensing film to make the piezoelectric sensing film reach a molten state.

2. The method according to claim 1, after performing recrystallization annealing on the piezoelectric sensing film, further including:
polishing an upper surface of the piezoelectric sensing film by a mechanical or mechanochemical polishing process, wherein a surface roughness index of the piezoelectric sensing film after polishing is lower than 10 nanometers.

3. The method according to claim 2, after polishing the upper surface of the piezoelectric sensing film, further including:
trimming the upper surface of the piezoelectric sensing film by an ion beam trimming process, wherein a surface thickness uniformity of the trimmed piezoelectric sensing film is less than 2%.

4. The method according to claim 1, wherein the piezoelectric sensing film is made of a material including lithium niobate, lithium tantalate, lithium tetraborate, bismuth germanate, lanthanum silicate, aluminum orthophosphate, potassium niobate, or a combination thereof.

5. The method according to claim 1, wherein performing recrystallization annealing treatment on the piezoelectric sensing film includes:
using furnace tube annealing to uniformly heat the first substrate, the liner layer deposited on the first substrate and the piezoelectric sensing film as a whole; or
using laser annealing to locally heat the piezoelectric sensing film to make it recrystallize.

6. The method according to claim 5, wherein:
the laser annealing includes performing the laser annealing on the piezoelectric sensing film in a vacuum, nitrogen, or oxygen atmosphere.

7. The method according to claim 5, wherein:
the piezoelectric sensing film is made of lithium niobate or lithium tantalate; and
performing recrystallization annealing treatment on the piezoelectric sensing film through the furnace tube annealing includes:
heating the first substrate, the liner layer, and the piezoelectric sensing film as a whole uniformly to 1100˜1300 Celsius degrees with a heating time of 5 to 30 seconds, and then cooling to room temperature, wherein the cooling rate is lower than 5 Celsius degrees per second.

8. The method according to claim 1, wherein forming the piezoelectric sensing film includes:
using a target with a purity higher than 99.99% to form the piezoelectric sensing film in a micro-crystalline state or an amorphous state, by a physical vapor deposition method.

9. The method according to claim 1, wherein:
the polycrystalline material layer is made of polycrystalline aluminum oxide, polycrystalline silicon dioxide, polycrystalline silicon carbide, or a combination thereof.

10. The method according to claim 1, wherein:
the liner layer further includes an acoustic wave reflection layer disposed between the first substrate and the polycrystalline material layer.

11. The method according to claim 10, wherein:
the acoustic wave reflection layer is made of a material including aluminum oxide, silicon dioxide, silicon nitride, silicon carbide, or a combination thereof.

12. The method according to claim 10, wherein:
the acoustic wave reflection layer and the polycrystalline material layer are the same layer, and the liner layer is made of a material including polycrystalline aluminum oxide, polycrystalline silicon dioxide, polycrystalline silicon carbide, or a combination thereof.

13. A composite substrate, comprising:
a first substrate;
a liner layer on the first substrate, wherein the liner layer includes at least a polycrystalline material layer; and
a piezoelectric sensing film for generating acoustic resonance on the polycrystalline material layer, wherein the piezoelectric sensing film is in a polycrystalline state.

14. The composite substrate according to claim 13, wherein:
the polycrystalline material layer is made of polycrystalline aluminum oxide, polycrystalline silicon dioxide, polycrystalline silicon carbide, or a combination thereof.

15. The composite substrate according to claim 13, wherein:
a thickness of the piezoelectric sensing film is about 0.01 μm to about 10 μm; and/or
a surface thickness uniformity of the piezoelectric sensing film is less than 2%.

16. The composite substrate according to claim 13, wherein:
the liner layer further includes an acoustic wave reflection layer disposed between the first substrate and the polycrystalline material layer, wherein:
the acoustic wave reflection layer is made of a material including aluminum oxide, silicon dioxide, silicon nitride, silicon carbide, or a combination thereof.

17. The composite substrate according to claim 16, wherein:
the acoustic wave reflection layer and the polycrystalline material layer are a same layer, and the liner layer is made of a material including polycrystalline aluminum oxide, polycrystalline silicon dioxide, polycrystalline silicon carbide, or a combination thereof.

18. The composite substrate according to claim 13, wherein:
the first substrate includes an acoustic wave reflection structure, wherein:
the acoustic wave reflection structure includes a cavity or a Bragg reflection layer.

19. A surface acoustic wave resonator, comprising a composite substrate, wherein:
the composite substrate includes: a first substrate; a liner layer on the first substrate including at least a polycrystalline material layer; and a piezoelectric sensing film for generating acoustic resonance on the polycrystalline material layer, wherein the piezoelectric sensing film is in a polycrystalline state.

20. A fabricating method of a surface acoustic wave resonator using a composite substrate according to claim 13, the method comprising:
providing a composite substrate, wherein:
the composite substrate includes: a first substrate; a liner layer on the first substrate including at least a polycrystalline material layer; and a piezoelectric sensing film for generating acoustic resonance on the polycrystalline material layer, wherein the piezoelectric sensing film is in a polycrystalline state; and
forming a first interdigital transducer and a second interdigital transducer on a piezoelectric sensing film.
